(19) United States
(12) Patent Application Publication
(10) Pub. No.: US 2026/0206464 A1
(43) Pub. Date: Jul. 16, 2026

(54) DISPLAY PANEL, METHOD FOR MANUFACTURING DISPLAY PANEL, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yiming Sha, Beijing (CN); Xiping Li, Beijing (CN); Shuang Liu, Beijing (CN); Pandeng Tang, Beijing (CN); Daiyong Liu, Beijing (CN); Mengqi Wang, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/506,734

(22) PCT Filed: Aug. 5, 2025
(86) PCT No.: PCT/CN2025/112727

§ 371 Date: Jan. 29, 2026

(30) Foreign Application Priority Data
Sep. 27, 2024 (CN) 202411367806.4

(51) Int. Cl. H10K 59/80; H10K 59/12

(52) U.S. Cl. CPC H10K 59/873; H10K 59/1201

(57) ABSTRACT

A display panel, a method for manufacturing the display panel, and a display device are provided. The display panel includes: a base substrate; at least one insulating layer arranged on the base substrate; an isolation pillar arranged on a side of the insulating layer distal to the base substrate, wherein a side surface of the isolation pillar is provided with an undercut structure; a light-emitting functional layer arranged on a side of the isolation pillar distal to the base substrate, wherein the light-emitting functional layer is disconnected at a position of the undercut structure; and an inorganic encapsulation layer arranged on a side of the light-emitting functional layer distal to the base substrate: wherein a first insulating layer in the at least one insulating layer is located in a first region where the isolation pillar is located.

### CROSS-REFERENCE TO RELATED APPLICATION

The present application claims a priority to the Chinese patent application No. 202411367806.4 filed in China on Sep. 27, 2024, a disclosure of which is incorporated herein by reference in its entirety.

### TECHNICAL FIELD

Embodiments of the present application relate to the field of display technology, and in particular, to a display panel, and a method for manufacturing the display panel, and a display device.

### BACKGROUND

Organic Light-Emitting Diode (OLED) display panels have advantages such as high color performance, high contrast ratio, fast response time, thin and lightweight profile, and flexibility, and are currently widely used. To achieve a full-screen design, a hole region can be formed in a display region (Active Area, AA) of the OLED display panel to arrange a camera or other sensors.

The light-emitting functional layer in an OLED display panel is typically arranged as an entire layer. After the hole region is formed in the AA of the display panel, a break is formed in the light-emitting functional layer at a cutting line position of the hole region, so that moisture and oxygen may enter through the break of the light-emitting functional layer, resulting in display defects.

### SUMMARY

Embodiments of the present application provide a display panel, a method for manufacturing the display panel, and a display device, for solving the problem in existing OLED display panels where a break occurs in the light-emitting functional layer at the cutting line position of the hole region, leading to moisture and oxygen ingress and resulting in display defects.

To solve the above technical problem, the present application is implemented as follows.

In a first aspect, an embodiment of the present application provides a display panel, including:
a base substrate;
at least one insulating layer arranged on the base substrate;
an isolation pillar arranged on a side of the insulating layer distal to the base substrate. wherein a side surface of the isolation pillar is provided with an undercut structure;
a light-emitting functional layer arranged on a side of the isolation pillar distal to the base substrate, wherein the light-emitting functional layer is disconnected at a position of the undercut structure; and
an inorganic encapsulation layer arranged on a side of the light-emitting functional layer distal to the base substrate;
wherein a first insulating layer in the at least one insulating layer is located in a first region where the isolation pillar is located, and a surface height of the first insulating layer in the first region is lower than a surface height of the first insulating layer in a second region located on both sides of the isolation pillar, and the first insulating layer is an insulating layer closest to the isolation pillar in the at least one insulating layer.

Optionally, the display panel includes a display region, a hole region located inside the display region, and a transition region located between the hole region and the display region; and the isolation pillar is located in the transition region, and arranged surrounding the hole region.

Optionally, the display panel further includes:
a first height-increasing patter arranged in the second region on both sides of the isolation pillar.

Optionally, the display panel includes a plurality of insulating layers; and the first height-increasing pattern is arranged between the plurality of insulating layers.

Optionally, the first height-increasing pattern includes at least one layer of gate metal pattern, and/or the first height-increasing pattern includes at least one layer of source/drain metal pattern.

Optionally, the display panel further includes:
a second height-increasing pattern arranged on a side of the isolation pillar proximate to the base substrate and located in the first region, wherein a height of the second height-increasing pattern is lower than a height of the first height-increasing pattern.

Optionally, the at least one insulating layer forms an etching groove in the first region where the isolation pillar is located, and an orthographic projection of the isolation pillar onto the base substrate is located within an orthographic projection of the etching groove onto the base substrate.

Optionally, the first insulating layer forms the etching groove.

Optionally, the isolation pillar includes a first film layer, a second film layer, and a third film layer sequentially arranged in a direction away from the base substrate, and a side surface of the second film layer is recessed inward relative to the first film layer and the third film layer to form the undercut structure; or
the isolation pillar includes a fourth film layer, a first film layer, a second film layer, and a third film layer sequentially arranged in a direction away from the base substrate, and a side surface of the second film layer is recessed inward relative to the first film layer and the third film layer to form the undercut structure.

Optionally, the isolation pillar includes at least one layer of source/drain metal pattern.

Optionally, the display panel includes a plurality of isolation pillars, and the plurality of isolation pillars are sequentially spaced apart in a direction from an edge of the transition region toward the display region.

In a second aspect, an embodiment of the present application provides a method for manufacturing a display panel, used for manufacturing the display panel according to the first aspect described above, and the method includes:
providing the base substrate;
forming the at least one insulating layer on the base substrate;
forming the isolation pillar on the side of the insulating layer distal to the base substrate, wherein the side surface of the isolation pillar is provided with the undercut structure;
forming the light-emitting functional layer on the side of the isolation pillar distal to the base substrate, wherein the light-emitting functional layer is disconnected at the position of the undercut structure;
forming the inorganic encapsulation layer on the side of the light-emitting functional layer distal to the base substrate;
wherein the first insulating layer in the at least one insulating layer is located in the first region where the isolation pillar is located, and the surface height of the first insulating layer in the first region is lower than the surface height of the first insulating layer in the second region located on both sides of the isolation pillar, and the first insulating layer is the insulating layer closest to the isolation pillar in the at least one insulating layer.

In a third aspect, an embodiment of the present application provides a display device, including the display panel according to the first aspect described above.

In the embodiments of the present application, by arranging the isolation pillar provided with the undercut structure, the light-emitting functional layer can be disconnected. Even if the break formed in the light-emitting functional layer due to cutting is penetrated by moisture and oxygen, it will not affect the light-emitting functional layer in the display region, thereby achieving the effect of isolating moisture and oxygen. In addition, the surface height of the first insulating layer in the first region where the isolation pillar is located is lower than the surface height of the first insulating layer in the second region located on both sides of the isolation pillar. This reduces the step difference between the height of the light-emitting functional layer in the first region where the isolation pillar is located and the light-emitting functional layer in the second region on both sides of the isolation pillar. As a result, when forming the inorganic encapsulation layer, more inorganic material accumulates at the interface between the first region and the second region, making a film layer of the inorganic encapsulation layer at the position of the undercut structure denser, so that the inorganic encapsulation layer is less likely to develop cracks at the position of the undercut structure, further preventing ingress of moisture and oxygen, and thereby improving the display effect.

### BRIEF DESCRIPTION OF THE DRAWINGS

Upon reading the detailed description of the preferred embodiments below, various other advantages and benefits will become apparent to those of ordinary skill in the art. The drawings are intended only to illustrate the preferred embodiments and are not to be considered as limiting the present application. Moreover, throughout the drawings, the same reference symbols are used to denote the same components. In the drawings:

FIG. 1 is a schematic structural diagram of an OLED display panel in the related art;

FIG. 2 is a top view of a display panel according to an embodiment of the present application;

FIG. 3 is a cross-sectional view of a display panel according to an embodiment of the present application;

FIG. 4 is another cross-sectional view of a display panel according to an embodiment of the present application;

FIG. 5 is a cross-sectional view of a display panel according to Embodiment 1 of the present application;

FIG. 6 is a cross-sectional view of a display panel according to Embodiment 2 of the present application;

FIG. 7 is a cross-sectional view of a display panel according to Embodiment 3 of the present application;

FIG. 8 is a cross-sectional view of a display panel according to Embodiment 4 of the present application;

FIG. 9 is a cross-sectional view of a display panel according to Embodiment 5 of the present application;

FIG. 10 is a cross-sectional view of a display panel according to Embodiment 6 of the present application;

FIG. 11 is a comparative schematic diagram at the position of the isolation pillar between the display panel according to an embodiment of the present application and a display panel in the related art;

FIG. 12 is a cross-sectional view of a display region of a display panel according to an embodiment of the present application;

FIG. 13 is a schematic flowchart of a manufacturing method of a display panel according to an embodiment of the present application;

FIG. 14 is a cross-sectional view of a display panel according to Embodiment 7 of the present application.

### DETAILED DESCRIPTION

The technical solutions in the embodiments of the present application will be clearly and completely described below with reference to the accompanying drawings in the embodiments of the present application. It is obvious that the described embodiments are only a part of the embodiments of the present application, but not all of them. All other embodiments obtained by a person of ordinary skill in the art based on the embodiments of the present application without creative efforts shall fall within the protection scope of the present application.

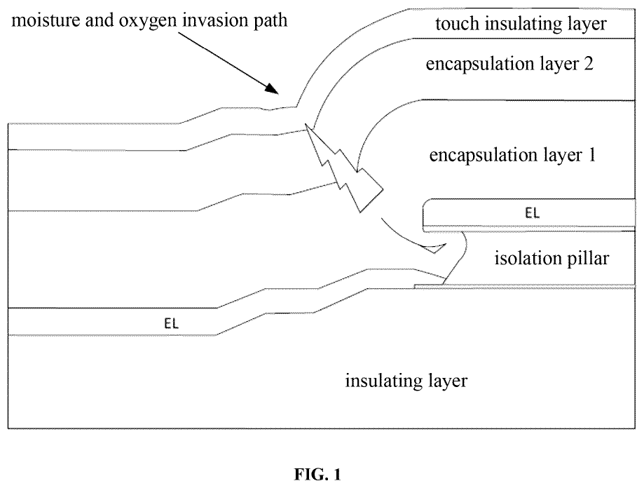

Refer to FIG. 1, which is a schematic structural diagram of an OLED display panel in the related art. In the related art, by arranging an isolation pillar with an undercut structure on the OLED display panel, the light-emitting functional layer can be disconnected. Even if the break formed in the light-emitting functional layer due to cutting is penetrated by moisture and oxygen, it will not affect the light-emitting functional layer in the display region, thereby achieving the effect of isolating moisture and oxygen. However, due to the undercut structure of the isolation pillar, the subsequently formed inorganic encapsulation layer may form a recess at the undercut position. The film layer of the inorganic encapsulation layer at the undercut position is thin and prone to cracking. Moisture can propagate along the crack path to the interface of the light-emitting functional layer, causing GDSH (black spots at the hole edge) phenomenon, which leads to display defects.

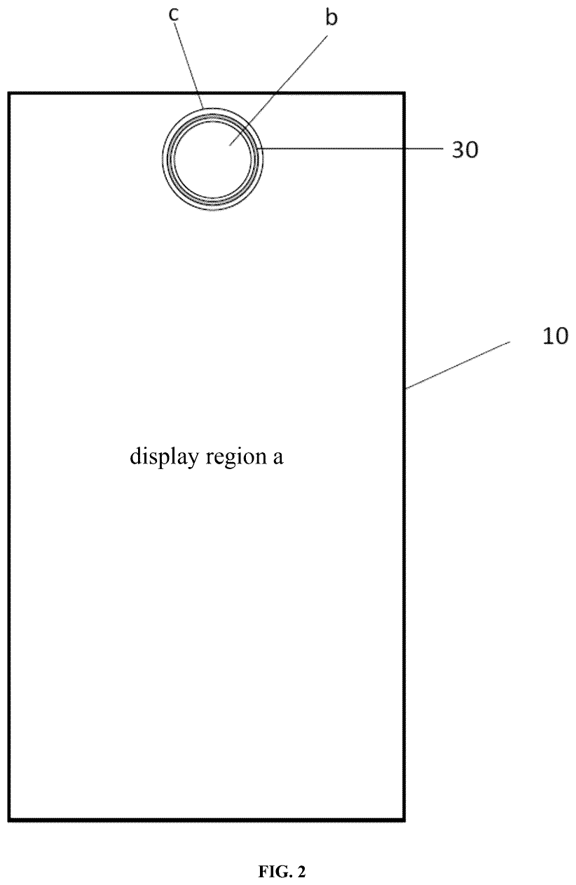

To solve the above problem, refer to FIGS. 2, 3, and 4. An embodiment of the present application provides a display panel, including:
a base substrate 10; the base substrate 10 may be a rigid base substrate, such as a glass substrate, or a flexible base substrate, such as a polyimide (PI) substrate, to achieve flexible display;
at least one insulating layer 20, arranged on the base substrate 10;
an isolation pillar 30, arranged on a side of the insulating layer 20 distal to the base substrate 10, wherein a side surface of the isolation pillar 30 is provided with an undercut structure;
a light-emitting functional layer 40, arranged on a side of the isolation pillar 30 distal to the base substrate 10, and disconnected at the position of the undercut structure; the light-emitting functional layer 40, besides including a light-emitting layer (EL), may also include at least one of: a hole transport layer, a hole injection layer, an electron transport layer, or an electron injection layer;
an inorganic encapsulation layer 50, arranged on a side of the light-emitting functional layer 40 distal to the base substrate 10;
wherein a first insulating layer in the at least one insulating layer 20 is located in a first region where the isolation pillar 30 is located, and a surface height of the first insulating layer in the first region is lower than a surface height of the first insulating layer in a second region located on both sides of the isolation pillar, and the first insulating layer is an insulating layer closest to the isolation pillar in the at least one insulating layer.

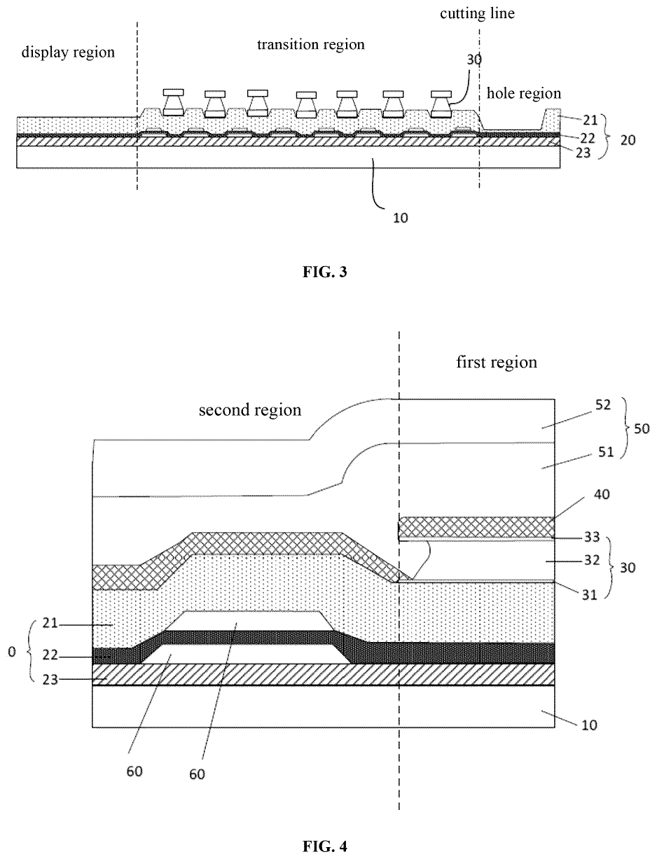

Comparing FIG. 1 and FIG. 4, it can be seen that in the related art, the surface height of the insulating layer closest to the isolation pillar in the first region where the isolation pillar is located is higher than the surface height of the insulating layer in the second region located on both sides of the isolation pillar, which causes the subsequently formed inorganic encapsulation layer to possibly create a depression at the undercut position. The film layer of the inorganic encapsulation layer at the undercut position is thin and prone to cracking. In contrast, in the embodiment of the present application, the surface height of the first insulating layer in the first region where the isolation pillar 30 is located is lower than the surface height of the first insulating layer in the second region located on both sides of the isolation pillar, so that when forming the inorganic encapsulation layer, more inorganic material accumulates at the interface between the first region and the second region, making the film layer of the inorganic encapsulation layer at the position of the undercut structure denser, so that the inorganic encapsulation layer is less likely to develop cracks at the position of the undercut structure.

In the embodiments of the present application, by arranging the isolation pillar provided with the undercut structure, the light-emitting functional layer can be disconnected. Even if the break formed in the light-emitting functional layer due to cutting is penetrated by moisture and oxygen, it will not affect the light-emitting functional layer in the display region, thereby achieving the effect of isolating moisture and oxygen. In addition, the surface height of the first insulating layer in the first region where the isolation pillar is located is lower than the surface height of the first insulating layer in the second region located on both sides of the isolation pillar. This reduces the step difference between the height of the light-emitting functional layer in the first region where the isolation pillar is located and the light-emitting functional layer in the second region on both sides of the isolation pillar. As a result, when forming the inorganic encapsulation layer, more inorganic material accumulates at the interface between the first region and the second region, making the film layer of the inorganic encapsulation layer at the position of the undercut structure denser, so that the inorganic encapsulation layer is less likely to develop cracks at the position of the undercut structure, further preventing ingress of moisture and oxygen, and thereby improving the display effect.

In some embodiments, optionally, the display panel has a display region a, a hole region b located inside the display region a, and a transition region c located between the hole region b and the display region a; the isolation pillar 30 is located in the transition region c, and arranged surrounding the hole region b.

Optionally, the at least one insulating layer 20 may be located in the display region a and the transition region c, the light-emitting functional layer 40 may be located in the display region a and the transition region c, and the inorganic encapsulation layer 50 may be located in the display region a and the transition region c.

Optionally, the hole region is used for arranging a camera or other sensors.

In the embodiments of the present application, by arranging the isolation pillar provided with the undercut structure, the light-emitting functional layer can be disconnected. Even if the break formed in the light-emitting functional layer in the transition region due to cutting is penetrated by moisture and oxygen, it will not affect the light-emitting functional layer in the display region, thereby achieving the effect of isolating moisture and oxygen. In addition, the surface height of the first insulating layer in the first region where the isolation pillar is located is lower than the surface height of the first insulating layer in the second region located on both sides of the isolation pillar. This reduces the step difference between the height of the light-emitting functional layer in the first region where the isolation pillar is located and the light-emitting functional layer in the second region on both sides of the isolation pillar. As a result, when forming the inorganic encapsulation layer, more inorganic material accumulates at the interface between the first region and the second region, making the film layer of the inorganic encapsulation layer at the position of the undercut structure denser, so that the inorganic encapsulation layer is less likely to develop cracks at the position of the undercut structure, further preventing ingress of moisture and oxygen, and thereby improving the display effect.

Obviously, in some other embodiments of the present application, the isolation pillar is not limited to being arranged surrounding the hole region. For example, in some embodiments, it may also be arranged surrounding the entire display region, located in a non-display region outside the display region.

Besides including the light-emitting functional layer, the display panel in the embodiments of the present application may further include an anode and a cathode, which are located in the display region. The anode, the light-emitting functional layer, and the cathode in the display region constitute a light-emitting unit of the display panel.

The inorganic encapsulation layer in the embodiments of the present application may include: a first inorganic encapsulation layer (CVD1) and/or a second inorganic encapsulation layer (CVD2) of the display panel.

The display panel in the embodiments of the present application may further include a drive circuit layer for driving the light-emitting unit to emit light. The base substrate, the drive circuit layer, and the aforementioned insulating layer constitute a backplane of the display panel. The drive circuit layer may include a thin-film transistor and a capacitor, and the thin-film transistor includes: a gate electrode, an active layer, a source electrode, and a drain electrode.

The insulating layer in the embodiments of the present application may be an insulating layer on the backplane, including at least one of the following: a barrier layer (Barrier), a buffer layer (Buffer), an interlayer dielectric layer (ILD), and a passivation layer (PVX).

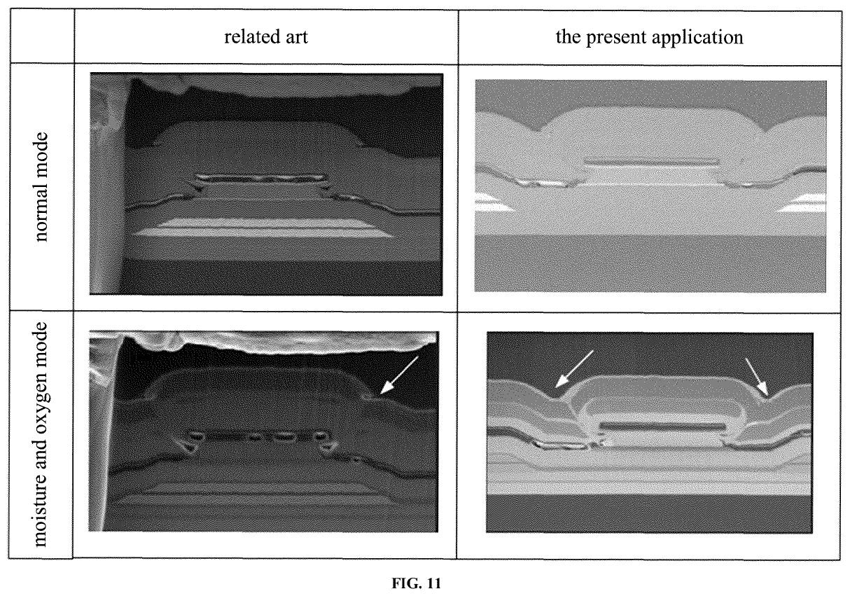

In some embodiments, optionally, refer to FIG. 4. The isolation pillar 30 includes a first film layer 31, a second film layer 32, and a third film layer 33 sequentially arranged in a direction away from the base substrate 10, and a side surface of the second film layer 32 is recessed inward relative to the first film layer 31 and the third film layer 33 to form the undercut structure. Obviously, the film layer structure of the isolation pillar 30 is not limited to this. For example, in some other embodiments of the present application, the isolation pillar 30 may include only the third film layer 33 and the second film layer 32, and the side surface of the second film layer 32 is recessed inward relative to the third film layer 33 to form the undercut structure. Refer to FIG. 10. In the embodiment shown in FIG. 10, the isolation pillar 30 includes a fourth film layer 34, a first film layer 31, a second film layer 32, and a third film layer 33 sequentially arranged in a direction away from the base substrate 10, and a side surface of the second film layer 32 is recessed inward relative to the first film layer 31 and the third film layer 33 to form the undercut structure.

In some embodiments, optionally, the first film layer 31, the second film layer 32, and the third film layer 33 of the isolation pillar 30 may be Ti/Al/Ti, respectively.

In some embodiments, optionally, the isolation pillar 30 includes at least one layer of source/drain (SD) metal pattern. That is, the isolation pillar 30 may be formed through a single patterning process together with the source/drain metal pattern in the display region of the display panel, for example, formed through a single patterning process together with a source/drain electrode of the thin-film transistor, thereby reducing process steps and lowering costs.

In the embodiment shown in FIG. 10, the fourth film layer may be a layer of source/drain (SD) metal pattern. The first film layer, the second film layer, and the third film layer constitute a layer of source/drain (SD) metal pattern. In some embodiments, the first film layer 31, the second film layer 32, and the third film layer 33 may be Ti/Al/Ti, respectively, while the fourth film layer may be a three-layer structure of Ti/Al/Ti.

In some embodiments, optionally, refer to FIGS. 2 and 3. The display panel includes a plurality of isolation pillars 30, and the plurality of isolation pillars 30 are sequentially spaced apart in a direction from an edge of the transition region toward the display region. In the embodiment shown in FIG. 2, the display panel includes 1 isolation pillar. In the embodiment shown in FIG. 3, the display panel includes 7 isolation pillars. Obviously, the number of isolation pillars is not limited to this. The more isolation pillars, the better the moisture and oxygen isolation effect.

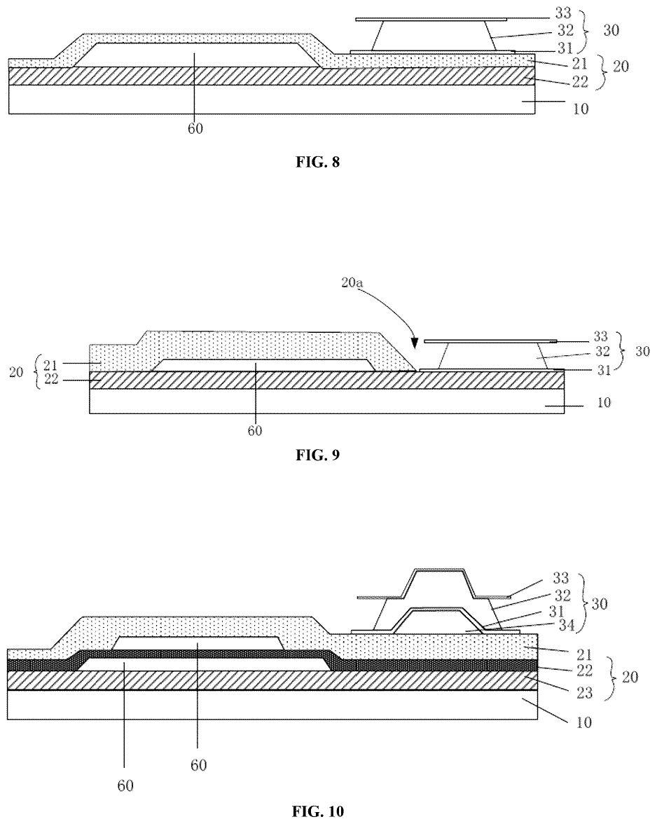

Refer to FIGS. 5 and 8. In some embodiments of the present application, optionally, the display panel further includes: a first height-increasing pattern 60, located in the transition region and arranged surrounding the hole region, arranged in the second region on both sides of the isolation pillar 30, that is, an orthographic projection of the first height-increasing pattern 60 onto the base substrate 10 does not overlap with an orthographic projection of the isolation pillar 30 onto the base substrate 10, and the isolation pillar 30 and the first height-increasing pattern 60 are arranged offset from each other. By arranging the first height-increasing pattern 60, the height of the insulating layer in the second region on both sides of the isolation pillar 30 can be raised, so that the surface height of the first insulating layer in the second region on both sides of the isolation pillar 30 is higher than the surface height of the first insulating layer in the first region where the isolation pillar 30 is located.

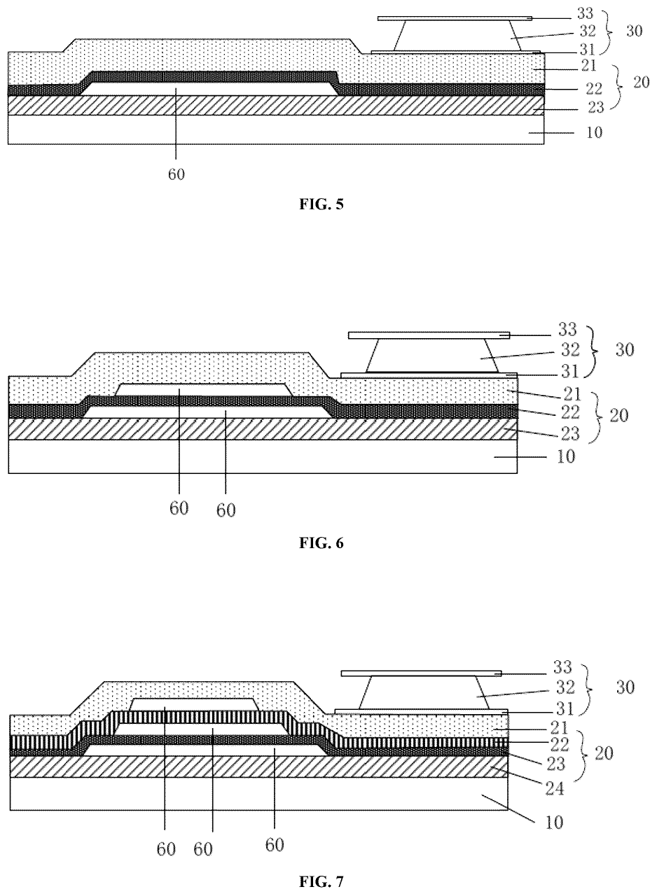

In the embodiments shown in FIGS. 5 and 8, the display panel includes one layer of the first height-increasing pattern 60. In some other embodiments of the present application, the display panel may include a plurality of first height-increasing patterns 60 stacked. Refer to FIGS. 6 and 7. In the embodiment shown in FIG. 6, the display panel may include two layers of stacked first height-increasing patterns 60. In the embodiment shown in FIG. 7, the display panel may include three layers of stacked first height-increasing patterns 60.

In some embodiments, optionally, the display panel includes a plurality of insulating layers 20. For example, in the embodiment shown in FIG. 8, the display panel includes two insulating layers, namely a first insulating layer 21 and a second insulating layer 22. In the embodiments shown in FIGS. 5 and 6, the display panel includes three insulating layers, namely a first insulating layer 21, a second insulating layer 22, and a third insulating layer 23. In the embodiment shown in FIG. 7, the display panel includes four insulating layers, namely a first insulating layer 21, a second insulating layer 22, a third insulating layer 23, and a fourth insulating layer 24. The first height-increasing pattern 60 is arranged between the plurality of insulating layers 20. Optionally, when the display panel includes a plurality of first height-increasing patterns, the plurality of first height-increasing patterns are separated from one another by the insulating layer.

In some embodiments, optionally, the first height-increasing pattern 60 includes at least one layer of gate metal pattern (refer to FIGS. 5, 6, and 7), and/or the first height-increasing pattern includes at least one layer of source/drain metal pattern (refer to FIG. 8). That is, at least one layer of the first height-increasing pattern 60 may be formed through a single patterning process together with the gate metal layer or source/drain metal pattern in the display region of the display panel, for example, formed through a single patterning process together with a gate electrode or a source/drain electrode of the thin-film transistor, thereby reducing process steps and lowering costs.

In the embodiments of the present application, the height of the gate metal pattern is generally between 2500 Å and 3000 Å. Therefore, arranging one layer of gate metal pattern in the second region is equivalent to raising the insulating layer in the second region by 2500 Å-3000 Å. Arranging one additional layer of gate metal pattern in the second region is equivalent to raising the insulating layer in the second region by an additional 2500 Å-3000 Å. The height of the source/drain metal pattern is generally greater than 3000 Å. Therefore, arranging one layer of source/drain metal pattern in the second region is equivalent to raising the insulating layer in the second region by a height greater than 3000 Å, resulting in a more pronounced height-increasing effect.

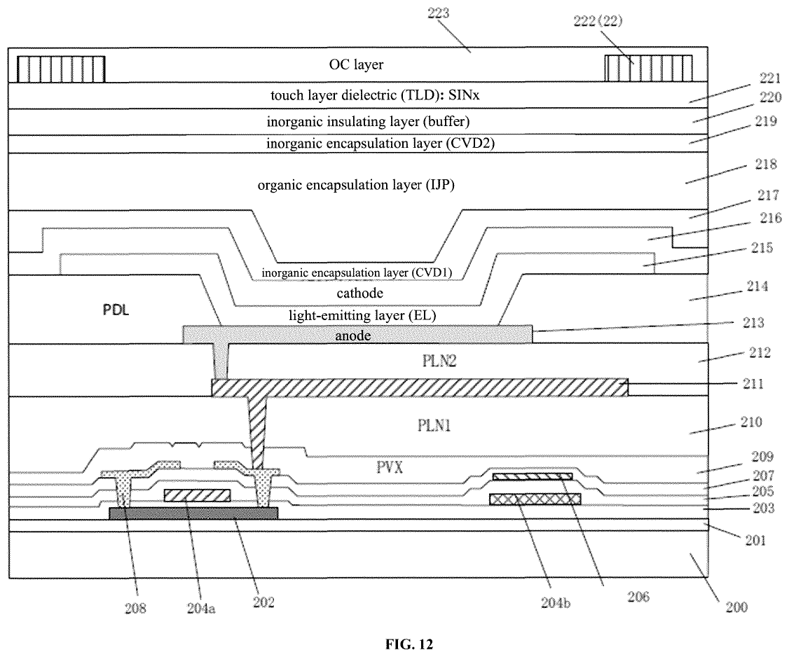

In some embodiments, the source/drain metal pattern used to form the first height-increasing pattern 60 and the source/drain metal pattern used to form the second film layer 32 of the isolation pillar 30 are not from the same source/drain metal layer. The source/drain metal pattern used to form the first height-increasing pattern 60 may be SD1, and the source/drain metal pattern used to form the second film layer 32 of the isolation pillar 30 may be SD2 or SD3. Alternatively, the source/drain metal pattern used to form the first height-increasing pattern 60 may be SD2, and the source/drain metal pattern used to form the second film layer 32 of the isolation pillar 30 may be SD3. The SD1 may be the first source/drain metal layer 208 in FIG. 12, the SD2 may be the second source/drain metal layer 211 in FIG. 12, and the SD3 is not shown in FIG. 12. The SD3 is a source/drain metal layer formed after SD2, insulated from SD2 by PLN and connected to SD2 through a via in the PLN layer.

In some embodiments, optionally, refer to FIG. 14. The display panel further includes: a second height-increasing pattern 70, located in the transition region and arranged surrounding the hole region, arranged on a side of the isolation pillar 30 proximate to the base substrate 10 and located in the first region; a height of the second height-increasing pattern 70 is lower than a height of the first height-increasing pattern 60. That is, the first region where the isolation pillar is located may also be increased in height, but the height-increasing amount in the first region needs to be less than the height-increasing amount in the second region on both sides of the isolation pillar, ensuring that the surface height of the first insulating layer in the first region where the isolation pillar 30 is located is lower than the surface height of the first insulating layer in the second region located on both sides of the isolation pillar. It should be noted that when the first height-increasing pattern 60 includes one or more layers, and the second height-increasing pattern 70 also includes one or more layers, the total height of the one or more second height-increasing patterns 70 is lower than the total height of the one or more first height-increasing patterns 60.

In some embodiments, refer to FIG. 9. Optionally, the at least one insulating layer 20 forms an etching groove 20a in the first region where the isolation pillar 30 is located, and an orthographic projection of the isolation pillar 30 onto the base substrate 10 is located within an orthographic projection of the etching groove 20a onto the base substrate 10. By forming the etching groove 20a on the at least one insulating layer in the first region, the surface height of the first insulating layer in the first region can be lowered, so that the surface height of the first insulating layer in the first region where the isolation pillar 30 is located is lower than the surface height of the first insulating layer in the second region located on both sides of the isolation pillar. In the embodiment shown in FIG. 9, besides forming the etching groove in the insulating layer 20 in the first region, the first height-increasing pattern 60 is also arranged in the second region.

Optionally, the etching groove is formed in the first insulating layer, that is, formed on the insulating layer closest to the isolation pillar 30, while other insulating layers may not be formed with such a groove. Obviously, it is not excluded that etching grooves are simultaneously formed in a plurality of insulating layers.

Refer to FIG. 11, which is a comparative schematic diagram at the position of the isolation pillar between a display panel according to an embodiment of the present application and a display panel in the related art. As can be seen from FIG. 11, the inorganic encapsulation layer in the related art forms a recess at the undercut position. The film layer is thin and prone to cracking. and severe moisture ingress occurs at the undercut structure of the isolation pillar. In contrast, the film layer of the inorganic encapsulation layer at the position of the undercut structure in the embodiment of the present application is denser, making the inorganic encapsulation layer less likely to develop cracks at the position of the undercut structure, and ingress of water/oxygen at the undercut structure of the isolation pillar is relatively slight.

The display panel in the embodiments of the present application may be an OLED display panel. Obviously, it is not excluded that the display panel may be other types of display panels.

The specific structure of the display region of the display panel in the embodiments of the present application is described below in conjunction with a cross-sectional view of the display panel. Refer to FIG. 12, which is a cross-sectional view of a display panel according to an embodiment of the present application. The display panel includes: a base substrate 200, and sequentially arranged on the base substrate 200: a buffer layer 201, an active layer 202, a first gate insulating layer 203, a first gate metal layer (including a gate electrode 204a and a first capacitor electrode 204b), a second gate insulating layer 205, a second gate metal layer (including a second capacitor electrode 206), an interlayer dielectric layer 207, a first source/drain metal layer 208 (including a source electrode and a drain electrode), a passivation layer (PVX) 209, a first planarization layer (PLN1) 210, a second source/drain metal layer 211, a second planarization layer (PLN2) 212, an anode 213, a pixel definition layer 214, a light-emitting layer (EL) 215, a cathode 216, a first inorganic encapsulation layer (CVD1) 217, an organic encapsulation layer (IJP) 218, a second inorganic encapsulation layer (CVD2) 219, an inorganic insulating layer (buffer) 220, a touch layer dielectric (TLD) 221, touch traces 222, and a flat layer (OC) 223.

The anode 213, the light-emitting layer (EL) 215, and the cathode 216 are used to form a light-emitting unit.

The active layer 202, the gate electrode 204a, the source electrode, and the drain electrode are used to constitute a thin-film transistor of a drive circuit. The drive circuit is used to drive the light-emitting unit to emit light. The first capacitor electrode 204b and the second capacitor electrode 206 are used to constitute a capacitor of the drive circuit.

The active layer in the embodiments of the present application may be made of a Low Temperature Polycrystalline Oxide (LTPO) material, that is, the display panel is an LTPO display panel.

The first height-increasing pattern in the above embodiments may be arranged in the same layer and made of the same material as at least one layer among the aforementioned first gate metal layer, second gate metal layer, first source/drain metal layer, and second source/drain metal layer.

The second height-increasing pattern in the above embodiments may also be arranged in the same layer and made of the same material as at least one layer among the aforementioned first gate metal layer, second gate metal layer, first source/drain metal layer, and second source/drain metal layer.

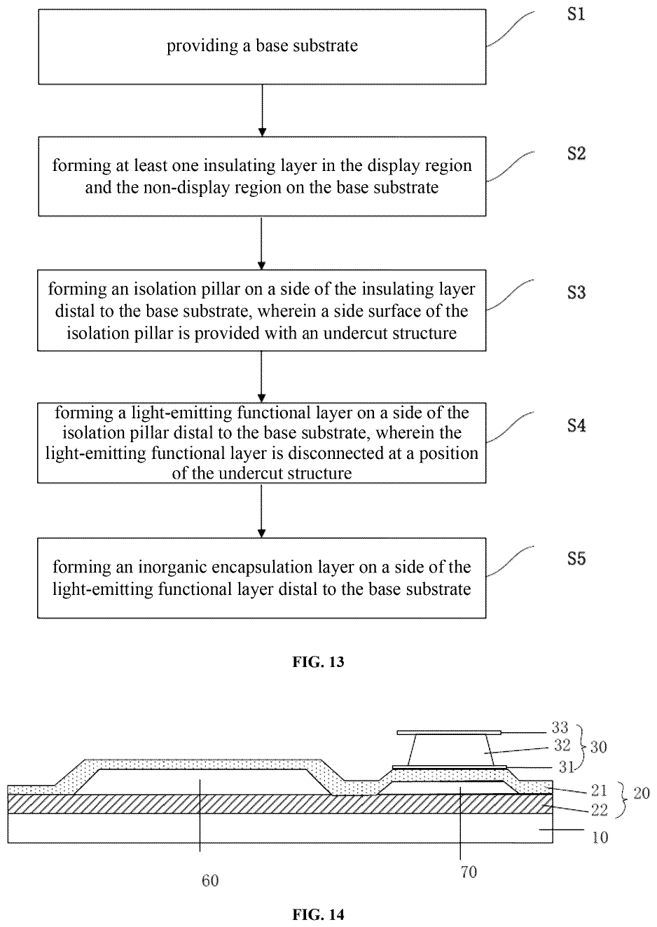

Refer to FIG. 13. An embodiment of the present application further provides a method for manufacturing a display panel, used for manufacturing the display panel according to any of the above embodiments. The method includes:
step S1: providing a base substrate;
step S2: forming at least one insulating layer on the base substrate;
step S3: forming an isolation pillar on a side of the insulating layer distal to the base substrate, wherein a side surface of the isolation pillar is provided with an undercut structure;
step S4: forming a light-emitting functional layer on a side of the isolation pillar distal to the base substrate, wherein the light-emitting functional layer is disconnected at a position of the undercut structure;
step S5: forming an inorganic encapsulation layer on a side of the light-emitting functional layer distal to the base substrate;
wherein a first insulating layer in the at least one insulating layer is located in a first region where the isolation pillar is located, and a surface height of the first insulating layer in the first region is lower than a surface height of the first insulating layer in a second region located on both sides of the isolation pillar, and the first insulating layer is an insulating layer closest to the isolation pillar in the at least one insulating layer.

In the embodiments of the present application, by arranging the isolation pillar provided with the undercut structure, the light-emitting functional layer can be disconnected. Even if the break formed in the light-emitting functional layer due to cutting is penetrated by moisture and oxygen, it will not affect the light-emitting functional layer in the display region, thereby achieving the effect of isolating moisture and oxygen. In addition, the surface height of the first insulating layer in the first region where the isolation pillar is located is lower than the surface height of the first insulating layer in the second region located on both sides of the isolation pillar. This reduces the step difference between the height of the light-emitting functional layer in the first region where the isolation pillar is located and the light-emitting functional layer in the second region on both sides of the isolation pillar. As a result, when forming the inorganic encapsulation layer, more inorganic material accumulates at the interface between the first region and the second region, making the film layer of the inorganic encapsulation layer at the position of the undercut structure denser, so that the inorganic encapsulation layer is less likely to develop cracks at the position of the undercut structure, further preventing ingress of moisture and oxygen, and thereby improving the display effect.

Optionally, the display panel has a display region, a hole region located inside the display region, and a transition region located between the hole region and the display region; and the isolation pillar is located in the transition region, and arranged surrounding the hole region.

Optionally, the method for manufacturing a display panel according to the embodiment of the present application further includes:
forming a first height-increasing pattern arranged in the second region on both sides of the isolation pillar.

Optionally, the display panel according to the embodiment of the present application includes a plurality of insulating layers; and the first height-increasing pattern is arranged between the plurality of insulating layers.

Optionally, the first height-increasing pattern includes at least one layer of gate metal pattern, and/or the first height-increasing pattern includes at least one layer of source/drain metal pattern.

Optionally, the method for manufacturing a display panel according to the embodiment of the present application further includes:
forming a second height-increasing pattern arranged on a side of the isolation pillar proximate to the base substrate and located in the first region; a height of the second height-increasing pattern is lower than a height of the first height-increasing pattern.

Optionally, the at least one insulating layer forms an etching groove in the first region where the isolation pillar is located, and an orthographic projection of the isolation pillar onto the base substrate is located within an orthographic projection of the etching groove onto the base substrate.

Optionally, the first insulating layer forms the etching groove.

Optionally, the isolation pillar includes a first film layer, a second film layer, and a third film layer sequentially arranged in a direction away from the base substrate, and a side surface of the second film layer is recessed inward relative to the first film layer and the third film layer to form the undercut structure; or
the isolation pillar includes a fourth film layer, a first film layer, a second film layer, and a third film layer sequentially arranged in a direction away from the base substrate, and a side surface of the second film layer is recessed inward relative to the first film layer and the third film layer to form the undercut structure.

Optionally, the isolation pillar includes at least one layer of source/drain metal pattern.

Optionally, the display panel includes a plurality of isolation pillars, and the plurality of isolation pillars are sequentially spaced apart in a direction from an edge of the transition region toward the display region.

An embodiment of the present application further provides a display device, including the display panel according to any of the above embodiments. The display device in the embodiments of the present application may be a mobile phone, a tablet computer, a personal computer, a television, an in-vehicle display device, etc.

The embodiments of the present application have been described above with reference to the accompanying drawings. However, the present application is not limited to the specific embodiments described above. The specific embodiments described above are merely illustrative rather than restrictive. Those of ordinary skill in the art, in light of the teachings of the present application, can make many modifications and variations without departing from the spirit of the present application and the scope defined by the claims, and all such modifications and variations fall within the protection scope of the present application.

1. A display panel, comprising:
a base substrate;
at least one insulating layer arranged on the base substrate;
an isolation pillar arranged on a side of the insulating layer distal to the base substrate, wherein a side surface of the isolation pillar is provided with an undercut structure;
a light-emitting functional layer arranged on a side of the isolation pillar distal to the base substrate, wherein the light-emitting functional layer is disconnected at a position of the undercut structure; and
an inorganic encapsulation layer arranged on a side of the light-emitting functional layer distal to the base substrate;
wherein a first insulating layer in the at least one insulating layer is located in a first region where the isolation pillar is located, and a surface height of the first insulating layer in the first region is lower than a surface height of the first insulating layer in a second region located on both sides of the isolation pillar, and the first insulating layer is an insulating layer closest to the isolation pillar in the at least one insulating layer.

2. The display panel according to claim 1, further comprising a display region, a hole region located inside the display region, and a transition region located between the hole region and the display region, wherein the isolation pillar is located in the transition region, and arranged surrounding the hole region.

3. The display panel according to claim 1, further comprising:
a first height-increasing pattern arranged in the second region on both sides of the isolation pillar.

4. The display panel according to claim 3, further comprising a plurality of insulating layers, wherein the first height-increasing pattern is arranged between the plurality of insulating layers.

5. The display panel according to claim 3, wherein the first height-increasing pattern comprises at least one layer of gate metal pattern, and/or the first height-increasing pattern comprises at least one layer of source/drain metal pattern.

6. The display panel according to claim 3, further comprising:
a second height-increasing pattern arranged on a side of the isolation pillar proximate to the base substrate and located in the first region, wherein a height of the second height-increasing pattern is lower than a height of the first height-increasing pattern.

7. The display panel according to claim 1, wherein
the at least one insulating layer forms an etching groove in the first region where the isolation pillar is located, and an orthographic projection of the isolation pillar onto the base substrate is located within an orthographic projection of the etching groove onto the base substrate.

8. The display panel according to claim 7, wherein the first insulating layer forms the etching groove.

9. The display panel according to claim 1, wherein the isolation pillar comprises a first film layer, a second film layer, and a third film layer sequentially arranged in a direction away from the base substrate, and a side surface of the second film layer is recessed inward relative to the first film layer and the third film layer to form the undercut structure; or
the isolation pillar comprises a fourth film layer, a first film layer, a second film layer, and a third film layer sequentially arranged in a direction away from the base substrate, and a side surface of the second film layer is recessed inward relative to the first film layer and the third film layer to form the undercut structure.

10. The display panel according to claim 1, wherein the isolation pillar comprises at least one layer of source/drain metal pattern.

11. The display panel according to claim 2, further comprising a plurality of isolation pillars, and the plurality of isolation pillars are sequentially spaced apart in a direction from an edge of the transition region toward the display region.

12. A method for manufacturing the display panel according to claim 1, wherein the method comprises:
providing the base substrate;
forming the at least one insulating layer on the base substrate;
forming the isolation pillar on the side of the insulating layer distal to the base substrate, wherein the side surface of the isolation pillar is provided with the undercut structure;
forming the light-emitting functional layer on the side of the isolation pillar distal to the base substrate, wherein the light-emitting functional layer is disconnected at the position of the undercut structure;
forming the inorganic encapsulation layer on the side of the light-emitting functional layer distal to the base substrate;
wherein the first insulating layer in the at least one insulating layer is located in the first region where the isolation pillar is located, and the surface height of the first insulating layer in the first region is lower than the surface height of the first insulating layer in the second region located on both sides of the isolation pillar, and the first insulating layer is the insulating layer closest to the isolation pillar in the at least one insulating layer.

13. A display device, comprising the display panel according to claim 1.

14. The display device according to claim 13, wherein the display panel further comprises a display region, a hole region located inside the display region, and a transition region located between the hole region and the display region, wherein the isolation pillar is located in the transition region, and arranged surrounding the hole region.

15. The display device according to claim 13, wherein the display panel further comprises:
a first height-increasing pattern arranged in the second region on both sides of the isolation pillar.

16. The display device according to claim 15, wherein the display panel further comprises a plurality of insulating layers, wherein the first height-increasing pattern is arranged between the plurality of insulating layers.

17. The display device according to claim 15, wherein the first height-increasing pattern comprises at least one layer of gate metal pattern, and/or the first height-increasing pattern comprises at least one layer of source/drain metal pattern.

18. The display device according to claim 15, wherein the display panel further comprises:
a second height-increasing pattern arranged on a side of the isolation pillar proximate to the base substrate and located in the first region, wherein a height of the second height-increasing pattern is lower than a height of the first height-increasing pattern.

19. The display device according to claim 13, wherein
the at least one insulating layer forms an etching groove in the first region where the isolation pillar is located, and an orthographic projection of the isolation pillar onto the base substrate is located within an orthographic projection of the etching groove onto the base substrate.

20. The display device according to claim 19, wherein the first insulating layer forms the etching groove.
